(19) United States
(12) Patent Application Publication
(10) Pub. No.: US 2023/0246128 A1
(43) Pub. Date: Aug. 3, 2023

(54) LIGHT-EMITTING DEVICE

(71) Applicant: TIANJIN SANAN OPTOELECTRONICS CO., LTD., Tianjin (CN)

(72) Inventors: Dongyan ZHANG, Tianjin (CN); Wen LIU, Tianjin (CN); Huiwen LI, Tianjin (CN); Chao JIN, Tianjin (CN); Kuoliang TANG, Tianjin (CN); Kuanfu PAN, Tianjin (CN); Duxiang WANG, Tianjin (CN)

(21) Appl. No.: 18/191,682

(22) Filed: Mar. 28, 2023

Related U.S. Application Data
(63) Continuation-in-part of application No. PCT/CN2021/071849, filed on Jan. 14, 2021.

(51) Int. Cl. H01L 33/22; H01L 33/62; H01L 33/60

(52) U.S. Cl. CPC H01L 33/22; H01L 33/62; H01L 33/60

(57) ABSTRACT

A light-emitting device includes a semiconductor epitaxial structure that has a first conductive semiconductor layer, a second conductive semiconductor layer, and an active layer disposed between the first conductive semiconductor layer and the second conductive semiconductor layer, a first mesa side wall that is defined by a side wall of the first conductive semiconductor layer and a side wall of the active layer, and a first mesa surface that is defined by a portion of a top surface of the second conductive semiconductor layer. The first mesa side wall has a side wall bottom end connected to the first mesa surface to form a connection portion, which is constituted of the side wall bottom end and a mesa surface proximal region of the first mesa surface that adjoins the side wall bottom end and is roughened. A method for manufacturing the light-emitting device is also disclosed.

### CROSS-REFERENCE TO RELATED APPLICATION

This application is a continuation-in-part (CIP) of International Application No. PCT/CN2021/071849, filed on Jan. 14, 2021, which is incorporated herein by reference in its entirety.

### FIELD

The disclosure relates to a semiconductor device, and more particularly to a light-emitting device and a manufacturing method of making the same.

### BACKGROUND

Light-emitting diodes (LEDs) offer advantages including high efficiency, long lifespan, etc. and have been widely applied in various fields, such as backlight, lighting, and display. Improving the light-emitting efficiency of the LEDs is a focus of current development in the industry.

The light-emitting efficiency of an LED is mainly determined by two factors: 1) the efficiency of recombination between electrons and holes in an active layer, and 2) the efficiency of light extraction.

Increasing the light-emitting efficiency of the LED includes a number of ways, such as improving the quality of epitaxial growth by increasing the recombination between electrons and holes, thereby improving the internal quantum efficiency (IQE). On the other hand, if light emitted by the LED is unable to be exacted effectively, a portion of the light is then reflected or refracted back and forth inside the LED and is eventually absorbed by an electrode or the active layer, and thus the luminous intensity of the LED is decreased. Therefore, roughening a surface of the LED or changing a geometric structure of the LED are often methods employed to enhance the external quantum efficiency (EQE), thereby increasing the luminous intensity and efficiency of the LED.

Mesa surfaces and side walls of a conventional LED are roughened so as to increase the light extraction efficiency and the luminous intensity. However, during the process of roughening, impurities may remain on side walls of the active layer, resulting in a current leakage and adversely affecting the performance of the conventional LED. If the side walls are not roughened, the luminous intensity of the LED is impacted.

### SUMMARY

Therefore, an object of the disclosure is to provide a light-emitting device that can alleviate at least one of the drawbacks of the prior art.

According to the disclosure, the light-emitting device includes a semiconductor epitaxial structure that has a first conductive semiconductor layer, a second conductive semiconductor layer, and an active layer disposed between the first conductive semiconductor layer and the second conductive semiconductor layer. The light-emitting device further includes a first mesa side wall that is defined by a side wall of the first conductive semiconductor layer and a side wall of the active layer, and a first mesa surface that is defined by a portion of a top surface of the second conductive semiconductor layer that is exposed from the active layer and the first conductive semiconductor layer. The first mesa side wall has a side wall bottom end connected to the first mesa surface to form a connection portion, which is constituted of the side wall bottom end and a mesa surface proximal region of the first mesa surface that adjoins the side wall bottom end. The mesa surface proximal region has a roughened structure.

A method for manufacturing the light-emitting device includes the steps of: S1) forming a semiconductor epitaxial structure that includes a first conductive semiconductor layer, a second conductive semiconductor layer, and an active layer disposed between the first semiconductor layer and the second conductive semiconductor layer; S2) roughening a surface of the first conductive semiconductor layer that is away from the active layer; S3) removing a portion of the first conductive semiconductor layer and of the active layer to form a first mesa surface and to expose a side wall of the active layer and a side wall of the first conductive semiconductor layer, the first mesa surface being defined by a portion of the second conductive semiconductor layer, the side walls of the active layer and the first conductive semiconductor layer defining a first mesa side wall.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a cross-sectional schematic view of a conventional light-emitting device according to the prior art.

FIG. 2 is a cross-sectional schematic view of a partially roughened first mesa surface of a light-emitting device according to a first embodiment.

FIG. 3 is an enlarged schematic view showing a connection portion of the light-emitting device according to the first embodiment.

FIG. 4 is a cross-sectional schematic view of an entirely roughened first mesa surface of the light-emitting device according to the first embodiment.

FIG. 5 is a cross-sectional schematic view of a second mesa surface being located on a reflection layer and the first mesa surface being entirely roughened according to a second embodiment.

FIG. 6 is a cross-sectional schematic view of the second mesa surface being located on the reflection layer and the first mesa surface being partially roughened according to the second embodiment.

FIG. 7 is a schematic view of an epitaxial structure provided in a manufacturing method according to a third embodiment, the epitaxial structure including a semiconductor epitaxial structure.

FIG. 8 is a schematic view of a structure obtained in the manufacturing method according to the third embodiment, after the semiconductor epitaxial structure is transferred onto a substrate by bonding and a growth substrate is removed.

FIG. 9 is a schematic view of the structure obtained in the manufacturing method according to the third embodiment, after a first electrode is formed on a second conductive semiconductor layer.

FIG. 10 is a schematic view of the structure obtained in the manufacturing method according to the third embodiment, after a surface of the semiconductor epitaxial structure is roughened.

FIG. 11 is a schematic view illustrating that the first mesa surface is formed according to the third embodiment.

FIG. 12 is a schematic view illustrating that the second mesa surface is formed according to the third embodiment.

FIG. 13 is a schematic view illustrating that an insulation layer and a second electrode are formed according to the third embodiment.

FIG. 14 is a schematic view of a packaged light-emitting device according to a fourth embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

Referring to FIG. 2, a light-emitting device according to the disclosure is provided and includes a substrate 100, a semiconductor epitaxial structure 1 which includes a first conductive semiconductor layer 101, an active layer 102 and a second conductive semiconductor layer 103, a dielectric layer 104, a reflection layer 105, a bonding layer 106, a first electrode 107, an insulation layer 108, a second electrode 109, a first mesa surface (S1), a second mesa surface (S2), and a first mesa side wall (S3) that is defined by a side wall of the first conductive semiconductor layer 101 and a side wall of the active layer 102.

The followings will describe each of the layers and mesa surfaces in greater details.

The substrate 100 is a conductive substrate and may be made of silicon, silicon carbide, or a metal. Examples of the metal include copper, tungsten, molybdenum, etc. In some embodiments, the substrate 100 has a thickness no smaller than 50 μm so as to have sufficient mechanical strength to support the semiconductor epitaxial structure. In addition, to facilitate further mechanical processing of the substrate 100 after bonding the substrate 100 to the semiconductor epitaxial structure, the substrate 100 may have a thickness that is no greater than 300 μm. In this embodiment, the substrate 100 is a silicon substrate.

The semiconductor epitaxial structure 1 includes the first conductive semiconductor layer 101, the second conductive semiconductor layer 103, and the active layer 102 disposed between the first conductive semiconductor layer 101 and the second conductive semiconductor layer 103.

The first conductive semiconductor layer 101 may be composed of group III-V or group II-VI compound semiconductors, and may be doped with a first dopant. In this embodiment, the first conductive semiconductor layer 101 may be made of a semiconductor material that is represented by Inₓ₁Al_{y1}Ga_{1-x1-y1}N, wherein 0≤x1≤1, 0≤y1≤1, and 0≤x1+y1≤1. The semiconductor material forming the first conductive semiconductor layer 101 may be selected from GaN, AlGaN, InGaN, InAlGaN, AlGaAs, GaP, GaAs, GaAsP, AlGaInP and combinations thereof. In addition, the first dopant may be an n-type dopant, such as Si, Ge, Sn, Se, or Te. When the first dopant is an n-type dopant, the first conductive semiconductor layer 101 doped with the first dopant becomes an n-type semiconductor layer. In this embodiment, the first conductive semiconductor layer 101 is an n-type semiconductor layer doped with an n-type dopant.

The active layer 102 is disposed between the first conductive semiconductor layer 101 and the second conductive semiconductor layer 103 so as to provide a region for recombination of electrons and holes to emit light. Depending on a wavelength of light that is to be emitted from the active layer 102, materials for the active layer 102 may vary. The active layer 102 may be a single quantum well or multiple quantum wells with a periodic structure. In some embodiments, the active layer 102 includes a well layer and a barrier layer, wherein the barrier layer has a bandgap that is greater than that of the well layer. By adjusting materials of the active layer 102, light having different wavelength may be emitted.

The second conductive semiconductor layer 103 is disposed on the active layer 102 and may be composed of group III-V or group II-VI compound semiconductors. The second conductive semiconductor layer 103 may be doped with a second dopant. In this embodiment, the second conductive type semiconductor layer 103 may be made of a semiconductor material that is represented by Inₓ₂Al_{y2}Ga_{1-x2-y2}N, wherein, 0≤x2≤1, 0≤y2≤1, and 0≤x2+y2≤1. The semiconductor materials forming the second conductive semiconductor layer 103 may be selected from AlGaAs, GaP, GaAs, GaAsP, AlGaInP and combinations thereof. When the second dopant is a p-type dopant, such as Mg, Zn, Ca, Sr, or Ba, the second conductive semiconductor layer 103 doped with the second dopant becomes a p-type semiconductor layer. In this embodiment, the second conductive semiconductor layer 103 is a p-type semiconductor layer doped with a p-type dopant.

The semiconductor epitaxial structure 1 may also include other layers, such as a current spreading layer, a window layer, an ohmic contact layer, etc. The multilayer structure of the semiconductor epitaxial structure 1 may have different numbers of layers according to varying doping concentrations or varying contents of components. The semiconductor epitaxial structure 1 may be formed on a growth substrate by physical vapor deposition (PVD), chemical vapor deposition (CVD), epitaxial growth technology, and atomic layer deposition (ALD), etc. In this embodiment, the semiconductor epitaxial structure 1 of the light-emitting device is made of an AlGaInP-based material and emits red light or infrared light.

The bonding layer 106 is a bonding metal material such as gold, tin, titanium, nickel, platinum, etc., and bonds the semiconductor epitaxial structure 1 to the substrate 100. The bonding layer 106 may be a single-layered structure or a multilayered structure, and may be made of a combination of multiple materials.

The reflection layer 105 is disposed on a side of the bonding layer 106 that is proximate the semiconductor epitaxial structure 1. In particular, the reflection layer 105 is located below the second conductive semiconductor layer 103, and the second mesa surface (S2) is located at a peripheral portion of the reflection layer 105 exposed from the second conductive semiconductor layer 103. A height of the second mesa surface (S2) is smaller than that of the first mesa surface (S1). The reflection layer 105 may be formed by a metal or an alloy including at least one of Ag, Ni, Al, Rh, Pd, Ir, Ru, Mg, Zn, Pt, Au, Hf, and combinations thereof. The reflection layer 105 may reflect light, which is emitted by the semiconductor epitaxial structure 1 toward the substrate 100, back to the semiconductor epitaxial structure 1 and enable the light to exit from a light-exiting surface of the semiconductor epitaxial structure 1. The light-exiting surface of the semiconductor structure 1 is located on a side of the first conductive semiconductor layer 101 that is away from the active layer 102.

The dielectric layer 104 is located on a side of the second conductive semiconductor layer 103 away from the active layer 102, and has a plurality of openings. The dielectric layer 104 may be made of an insulating material having a conductivity smaller than that of the reflection layer 105, a material having a low conductivity, or a material that can be in Schottky contact with the second conductive semiconductor layer 103. For example, the dielectric layer 104 may be made from a composition including at least one of fluorides, nitrides, and oxides, specifically at least one of ZnO, SiO₂, SiOₓ, SiOₓN_{y}, Si₃N₄, Al₂O₃, TiOₓ, MgF, GaF, and a combination thereof. The dielectric layer 104 may have at least one layer of a dielectric material or multiple layers of the dielectric material having different refractive indices. In some embodiments, the dielectric layer 104 is a light-transmissive dielectric layer capable of allowing at least 50% of the light to pass therethrough. In other embodiments, an index of refraction of the dielectric layer 104 is smaller than that of the semiconductor epitaxial structure 1.

The reflection layer 105 and the dielectric layer 104 may also include an ohmic contact layer (not shown in the figures) therebetween. The ohmic contact layer may fill multiple openings of the dielectric layer 104 to form multiple discrete ohmic contact spots for contact with the second conductive semiconductor layer 103, thereby uniformly delivering electric current from the reflection layer 105 and the bonding layer 106 to the semiconductor epitaxial structure 1. Therefore, in this case, the ohmic contact layer does not contact the side of the second conductive semiconductor layer 103 away from the active layer 102 entirely. The ohmic contact layer may be a transparent conductive layer formed of, for example, at least one of ITO, IZO, IZTO, IAZO, IGZO, IGTO, AZO, and ATO. Alternatively, the ohmic contact layer may also use a light transmitting conductive material and metal. The metal may be an alloy material such as Au—Zn, Au—Ge, Au—Ge—Ni, or Au—Be, and the ohmic contact layer may have a single-layered or a multilayered structure.

The reflection layer 105 and the dielectric layer 104 may form an Omni-Directional Reflector (ODR) structure, which may reflect light, which is emitted by the semiconductor epitaxial structure 1 toward the substrate 100, back to the semiconductor epitaxial structure 1 and enable the light to exit from the light-exiting surface of the semiconductor epitaxial structure 1, thereby increasing the light-emitting efficiency.

In the prior art, to improve the light-emitting efficiency of light emitted from the active layer 102, and from a light-exiting surface and a side wall of a conventional light-emitting device, the light-exiting surface and the side wall of the conventional light-emitting device are roughened. However, during roughening, impurities may remain on a side wall of the semiconductor epitaxial structure, resulting in a current leakage.

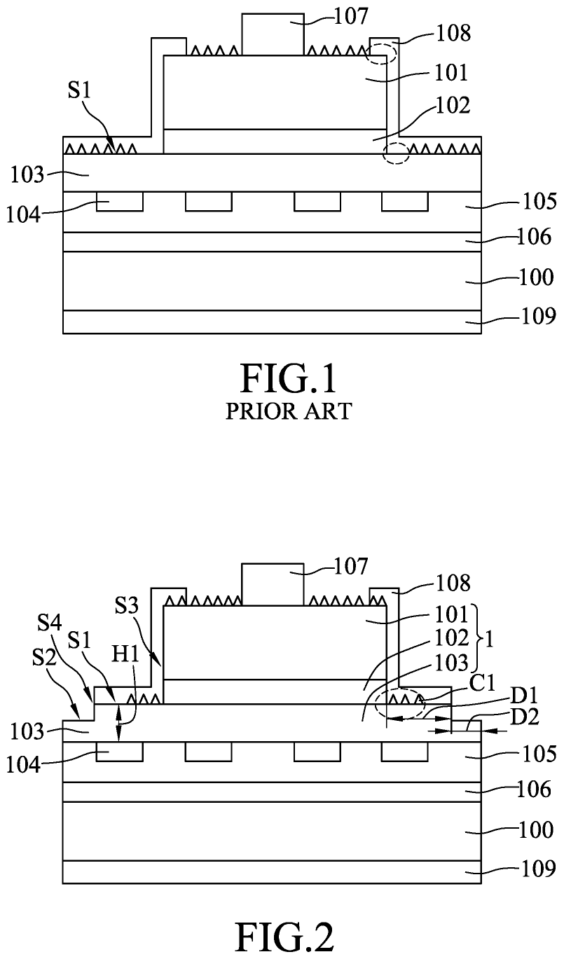

To resolve the issue of current leakage, a mask (not shown) is formed to cover and protect the side wall so as to prevent it from being roughened. Referring to the dashed circles in FIG. 1, because of the mask, a surface of an upper corner of the first conductive semiconductor layer 101 is not roughened, and a region of the first mesa surface (S1) adjoining a bottom end of the first mesa side wall is also not roughened. Such will adversely affect the luminous intensity of the light-emitting device.

To alleviate this drawback of the prior art, referring to FIG. 2, the light-emitting device further includes a first electrode 107 disposed on and electrically connected to a top surface of the first conductive semiconductor layer 101. The top surface of the first conductive semiconductor layer 101 has at least one roughened region that is outside the first electrode 107 and that is roughened. In this embodiment, the roughened region of a top surface of the first conductive semiconductor layer 101 is a surrounding region that surrounds the first electrode 107 and is roughened. A width of the roughened region or the surrounding region of the first conductive semiconductor layer 101 ranges from 0.5 μm to 3 μm. A surface roughness of the first mesa side wall (S3) is smaller than that of the roughened region of the first conductive semiconductor layer 101. In certain embodiment, the surface roughness of the roughened region on the first conductive semiconductor layer 101 ranges from 0.2 μm to 1 μm. The surface roughness of the first mesa side wall (S3) is no greater than 0.2 μm. In particular, each of the side walls of the active layer 102 and the first conductive semiconductor layer 101, which define the first mesa side wall (S3), has a surface roughness that is no greater than 0.2 μm.

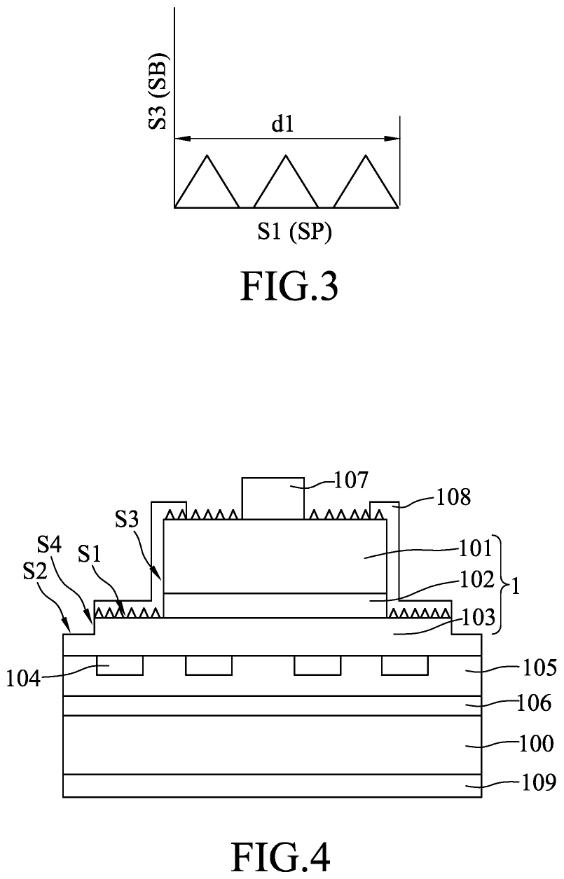

The light-emitting device further includes the first mesa surface (S1). As shown in FIGS. 2 and 3, the first mesa surface (S1) is formed on the second conductive semiconductor layer 103 and does not overlap the active layer 102. The first mesa surface (S1) is defined by a portion of a top surface of the second conductive semiconductor layer 103 that is exposed from the active layer 102 and the first conductive semiconductor layer 103. The first mesa side wall (S3) has a side wall bottom end (SB) connected to the first mesa surface (S1) to form a connection portion (C1). FIG. 3 is a partially enlarged view illustrating the connection portion (C1). The connection portion (C1) is constituted of the side wall bottom end (SB) of the first mesa side wall (S3) and a mesa surface proximal region (SP) of the first mesa surface (S1) that adjoins the side wall bottom end (SB) of the first mesa side wall (S3). The mesa surface proximal region (SP) of the first mesa surface (S1) has a roughened structure, which has a surface roughness ranging from 0.2 μm to 1 μm. The side wall bottom end (SB) of the first mesa side wall (S3) is not roughened. The first mesa surface (S1) may further have a distal region that is outside the mesa surface proximal region (SP) of the first mesa surface (S1) and that also has a roughened structure (see FIG. 4). A width (d1) of the mesa surface proximal region (SP) ranges from 0.5 μm to 3 μm. A surface roughness of the first mesa side wall (S3) is no greater than 0.2 μm. A distance (D1) from an edge of the first mesa surface (S1) to the first mesa side wall (S3) may range from 0.5 μm to 10 μm. In some embodiments, the distance (D1) from the edge of the first mesa surface (S1) to the first mesa side wall (S3) ranges from 4 μm to 7 μm.

In some embodiments, as shown in FIG. 2, the first mesa surface (S1) further includes a non-roughened region located distally to the first mesa side wall (S3) and proximally to a boundary of the semiconductor epitaxial structure 1.

In certain embodiments, an entire of the first mesa surface (S1) is roughened as shown in FIG. 4. In some embodiments, the surface roughness of the first mesa surface (S1) ranges from 0.2 μm to 1 μm. A surface roughness of the first mesa side wall (S3) is smaller than that of the first mesa surface (S1). A surface roughness of the first mesa side wall (S3) is no greater than 0.2 μm.

The roughened structure of the first mesa surface (S1) may enhance the light emitted from the first mesa surface (S1) of the active layer 102, thereby enhancing the luminous intensity of the light-emitting device.

The light-emitting device of the disclosure further includes a second mesa surface (S2), as shown in FIG. 2, located on the second conductive semiconductor layer 103, exposes a second mesa side wall (S4) of the second conductive semiconductor layer 103, and disposed around the first mesa surface (S1). The second mesa side wall (S4) is defined by a side wall of the second conductive semiconductor layer 103 and intersects the second mesa surface (S2). A distance (D2) from an edge of the second mesa surface (S2) to the second mesa side wall (S4) may range from 0.1 μm to 30 μm. In certain embodiments, the distance (D2) from the edge of the second mesa surface (S2) to the second mesa side wall (S4) ranges from 8 μm to 15 μm. The second mesa surface (S2) has a height (H1) that is smaller than that of the first mesa surface (S1) and that ranges from 0.2 μm to 3.5 μm. The second mesa surface (S2) has a surface roughness that is smaller than that of the first mesa surface (S1). The surface roughness of the second mesa surface (S2) is no greater than 0.2 μm.

The light emitted from the active layer 102 may be radiated at the second mesa side wall (S4) of the light-emitting device. Since the second conductive semiconductor layer 103 absorbs light, the second mesa surface (S2) is provided to reduce light absorption of the second conductive semiconductor layer 103, thereby enhancing the luminous intensity of the light-emitting device. Furthermore, the second mesa surface (S2) may facilitate dicing and die bonding in later processes.

The first electrode 107 is disposed on the light-exiting surface of the semiconductor epitaxial structure 1. In some embodiments, the first electrode 107 may include a pad electrode and an extension electrode, wherein the pad electrode is mainly used for external wire bonding in packaging. A shape of the pad electrode may vary to be a cylinder, a block or other polygonal shapes based on actual requirements of wire bonding. The extension electrode may have a pre-designed shape, which may vary. Specifically, the extension electrode may be strip-shaped.

The light-emitting device further includes a second electrode 109. In this embodiment, the second electrode 109 is formed entirely on a surface of the substrate 100 that is away from the bonding layer 106. The substrate 100 of this embodiment is a conductive supporting substrate. With the first electrode 107 and the second electrode 109 formed on opposite sides of the substrate 100, current may flow vertically through the semiconductor epitaxial structure 1 so as to provide a uniform current density.

The first electrode 107 and the second electrode 109 may be made of metallic materials. Of the first electrode 107, at least the pad electrode and the extension electrode include metallic materials, which may enable a good ohmic contact with the semiconductor epitaxial structure 1.

The light-emitting device further includes an insulation layer 108 covering the surfaces and side walls of the first conductive semiconductor layer 101 and the active layer 102 so as to protect the light-emitting device from environmental damages, such as moisture or mechanical harms.

In some other embodiments, the insulation layer 108 may further cover an edge and a side wall of the first electrode 107.

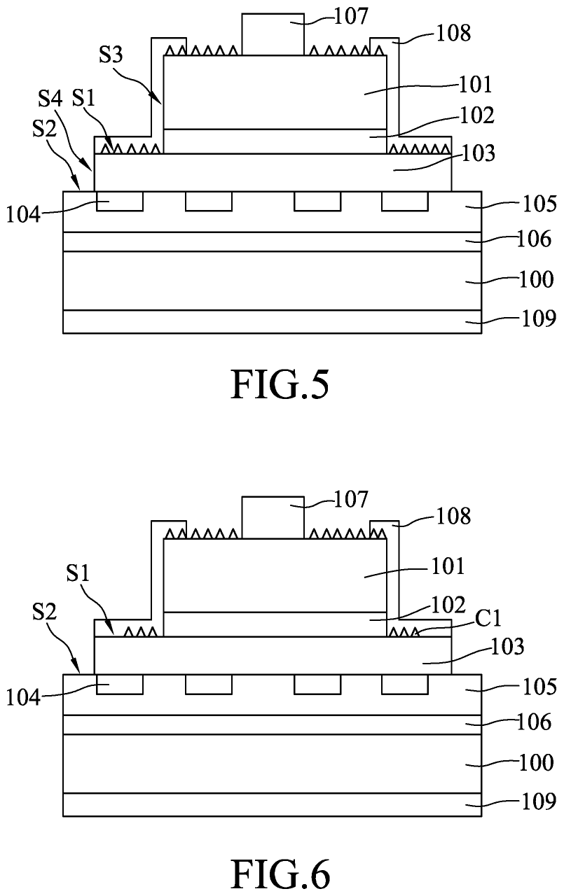

Referring to FIG. 5, which illustrates a second embodiment of the disclosure, the difference between the second embodiment and the first embodiment resides in that the second mesa surface (S2) of the second embodiment becomes lower because the second conductive semiconductor layer 103 is etched through an entire thickness of the second conductive semiconductor layer 103; the second mesa surface (S2) is located near an edge of the light-emitting device and on the reflection layer 105. Since the second conductive semiconductor layer 103 absorbs light, the second mesa surface (S2) is provided to reduce the light absorption of the second conductive semiconductor layer 103, thereby enhancing the luminous intensity of the light-emitting device. As shown in FIG. 5, the surface of the first mesa surface (S1) is entirely roughened.

In some embodiments, as shown in FIG. 6, the first mesa surface (S1) has a roughened region and a non-roughened region. The roughened region is the mesa surface proximal region (SP) of the connection portion (C1). The non-roughened region is proximate to the boundary of the semiconductor epitaxial structure 1.

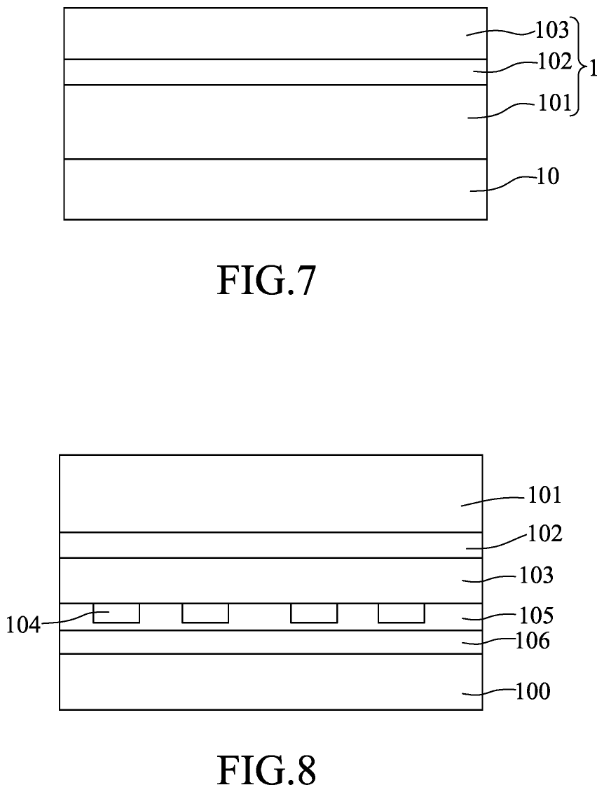

Referring to FIG. 7, a third embodiment of the disclosure including a method for manufacturing the light-emitting device of the first and second embodiments is provided below.

FIG. 7 illustrates an epitaxial structure. First, a growth substrate 10 that may be made of gallium arsenide is provided. By using an epitaxy process, such as metal-organic chemical vapor deposition (MOCVD), the semiconductor epitaxial structure 1 is grown on the growth substrate 10. The semiconductor epitaxial structure 1 includes the first conductive semiconductor layer 101, the second conductive semiconductor layer 103, and the active layer 102 disposed between the first conductive semiconductor layer 101 and the second conductive semiconductor layer 103. In some embodiments, the semiconductor epitaxial structure 1 is made of an AlGaN-based material that emits red light or infrared light.

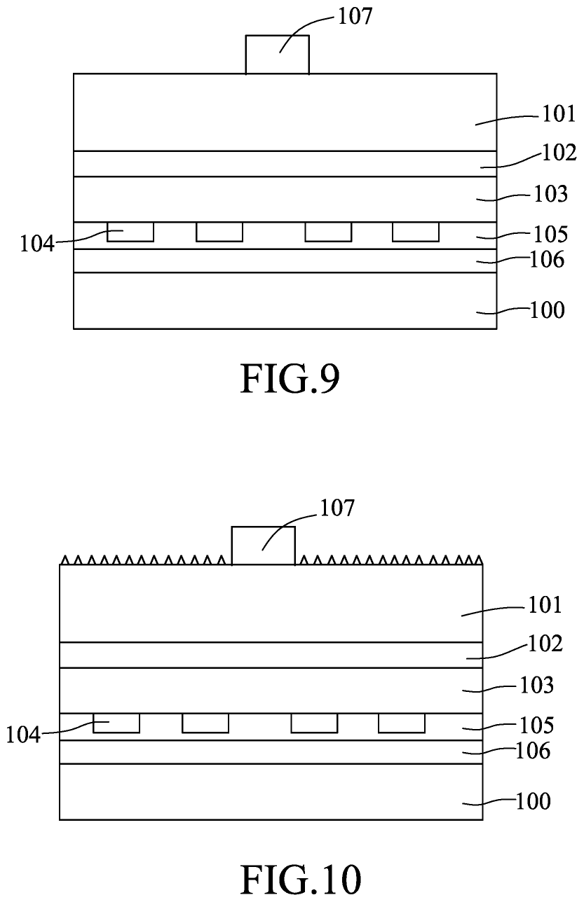

Next, the dielectric layer 104 is disposed on the side of the second conductive semiconductor layer 103 away from the active layer 102. In certain embodiments, the dielectric layer 104 is made of SiO₂ or MgF₂. In this embodiment, masking and etching are performed so as to form openings in the dielectric layer 104. Then, the reflection layer 105 is disposed on a surface of the dielectric layer 104 away from the second conductive semiconductor layer 103. The bonding layer 106 is disposed on a surface of the reflection layer 105 away from the dielectric layer 104, and bonds with the substrate 100 via a bonding process. Next, the growth substrate 10 is removed using wet etching to obtain a structure as shown in FIG. 8. Subsequently, referring to FIG. 9, the first electrode 107 is formed on the first conductive semiconductor layer 101, which may include the pad electrode for wire bonding and the extension electrode, wherein the pad electrode and the extension electrode provide a position for wire bonding and an effect of horizontal current spreading, respectively.

Then, as shown in FIG. 10, a surface of the first conductive semiconductor layer 101 away from the active layer 102 is roughened by masking and etching. In this embodiment, wet etching is performed, by using one or more agents selected from sulfuric acid, phosphoric acid, nitric acid, acetic acid, oxalic acid, hydrofluoric acid, or a combination thereof.

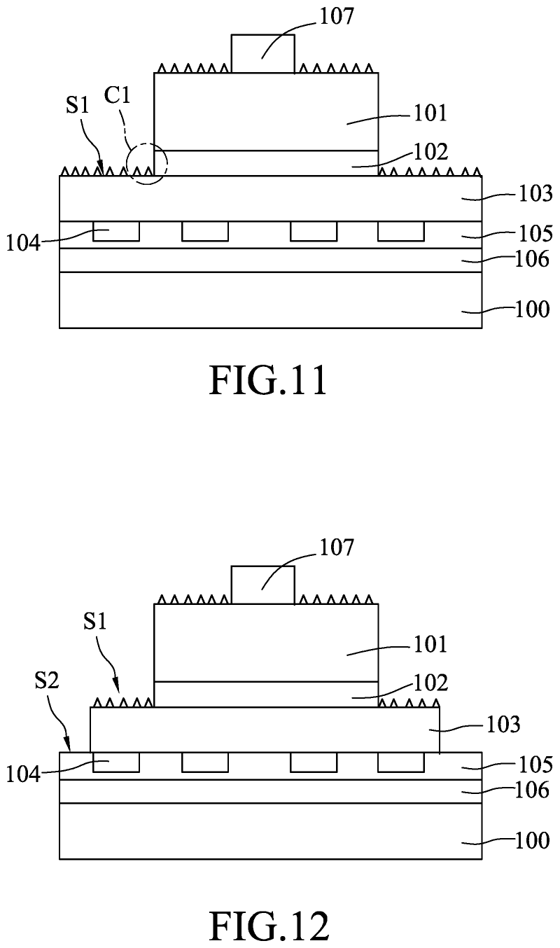

Subsequently, as shown in FIG. 11, dry etching is used to remove a portion of the first conductive semiconductor layer 101 and of the active layer 102 to form the first mesa surface (S1) and to expose a side wall of the first conductive semiconductor layer 101 and a side wall of the active layer 102. The first mesa surface (S1) is defined by a portion of the second conductive semiconductor layer 103. The side walls of the active layer 102 and the first conductive semiconductor layer 101, which are exposed, define the first mesa side wall.

The first mesa side wall has the side wall bottom end that connects the mesa surface proximal region of the first mesa surface (S1) and forms the connection portion (C1), which is constituted of the side wall bottom end of the first mesa side wall and the mesa surface proximal region of the first mesa surface (S1) that adjoins the side wall bottom end. The mesa surface proximal region has a roughened structure, which may facilitate the light emitted from the active layer 102 to exit from the first mesa surface (S1), thereby increasing the luminous intensity of the light-emitting device. In some alternative embodiments, the first mesa surface (S1) is entirely roughened. In other embodiments, the distal portion of the first mesa surface (S1) is not roughened. In the next step, as shown in FIG. 12, masking and dry etching are used to remove a portion of the second conductive semiconductor layer 103 to form the second mesa surface (S2) and to expose the second mesa side wall.

The reflection layer 105 is formed on the second conductive semiconductor layer 103 opposite the active layer 102. The portion of the second conductive semiconductor layer 103 is removed by etching through an entire thickness of the second semiconductor layer 103 to expose a portion of the reflection layer 105 and thereby forming the second mesa surface on a top surface of the reflection layer 105 and exposing the second mesa side wall of the second conductive semiconductor layer 103. In some embodiment, the second mesa surface is formed on the second conductive semiconductor layer 103. A height of the second mesa surface is smaller than that of the first mesa surface (S1).

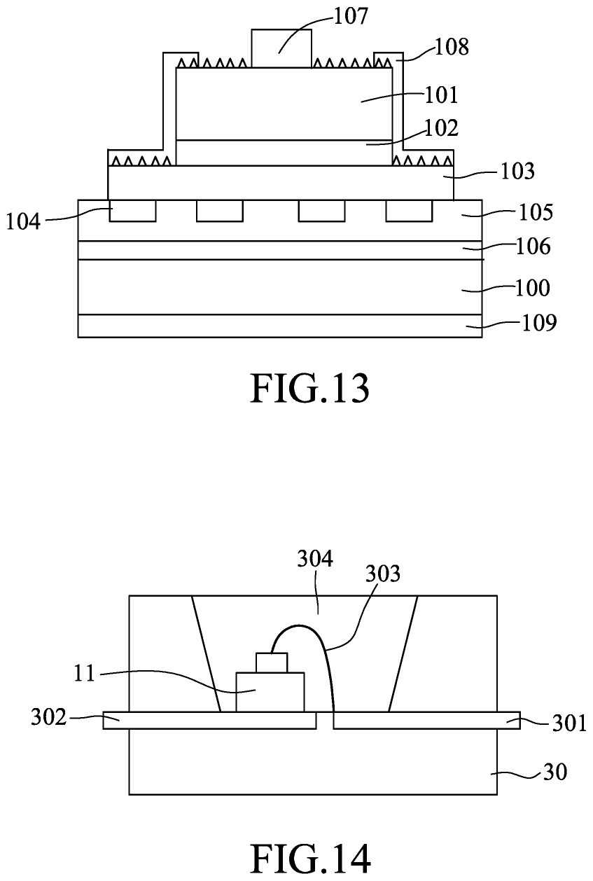

Referring to FIG. 13, the insulation layer 108 is formed on the surface of the first conductive semiconductor layer 101 away from the active layer 102 and on the side walls of the first conductive semiconductor layer 101 and the active layer 102. The second electrode 109 is formed on the surface of the substrate 100 away from the bonding layer 106.

According to this method of the present disclosure, by virtue of roughening the mesa surfaces, the first conductive semiconductor layer 101 and the first mesa surface (S1) may have roughened structures. By keeping the side walls of the first conductive semiconductor layer 101 and the active layer 102 not roughened, the problem of current leakage due to roughening of the side walls may be resolved. The roughening of the first conductive semiconductor layer 101 and the first mesa surface (S1) may also enhance light-exiting of the light-emitting device, thereby increasing the light-emitting efficiency of the light-emitting element. The present disclosure further provides a method of forming the second mesa surface (S2), which may reduce the light absorption of the second conductive semiconductor layer 103 and increase radiation of the light emitted by the active layer 102 from the second mesa side wall (S4), which may further increase the luminous intensity of the light-emitting device.

The light-emitting device according to the present disclosure may widely be applied in fields such as display, indoor lighting, plant lighting, etc.

Specifically, referring to FIG. 14, a packaged light-emitting device according to a fourth embodiment of the disclosure is illustrated and includes a packaging substrate 30, the light-emitting device 11, and sealing resin 304. At least one of the light-emitting devices 11 according to the aforementioned embodiments is disposed on the packaging substrate 30, which may be a printed circuit board (PCB), such as a metal core printed circuit board (MCPCB), a metal printed circuit board (MPCB), or a flexible printed circuit board (FPCB). A surface of the packaging substrate 30 has a first electrode 301 and a second electrode 302 that are electrically isolated. The light-emitting device 11 is disposed on the surface of the packaging substrate 30 (i.e., on the same side as the first and second electrodes 301, 302), and is electrically connected to the packaging substrate 30 by a conductive wire 303. The sealing resin 304 may include a wavelength-converting material, such as phosphor and/or a quantum dot. The sealing resin 304 has a dome-shaped lens structure having an upper convex surface and may adjust an angle at which the light is emitted by different structures.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a semiconductor epitaxial structure that includes a first conductive semiconductor layer, a second conductive semiconductor layer, and an active layer disposed between said first conductive semiconductor layer and said second conductive semiconductor layer;
a first mesa side wall that is defined by a side wall of said first conductive semiconductor layer and a side wall of said active layer;
a first mesa surface that is defined by a portion of a top surface of said second conductive semiconductor layer that is exposed from said active layer and said first conductive semiconductor layer;
wherein said first mesa side wall has a side wall bottom end connected to said first mesa surface to form a connection portion which is constituted of said side wall bottom end and a mesa surface proximal region of said first mesa surface that adjoins said side wall bottom end, said mesa surface proximal region having a roughened structure.

2. The light-emitting device as claimed in claim 1, wherein said roughened structure of said mesa surface proximal region has a surface roughness ranging from 0.2 μm to 1 μm, a width of said mesa surface proximal region ranging from 0.5 μm to 3 μm.

3. The light-emitting device as claimed in claim 1, wherein said first mesa surface further has a distal region that is outside said mesa surface proximal region of said first mesa surface and that has a roughened structure.

4. The light-emitting device as claimed in claim 1, wherein a surface roughness of said first mesa side wall is no greater than 0.2 μm.

5. The light-emitting device as claimed in claim 1 further comprising a first electrode disposed on and electrically connected to a top surface of said first conductive semiconductor layer, said top surface of said first conductive semiconductor layer having at least one roughened region that is outside said first electrode and that is roughened.

6. The light-emitting device as claimed in claim 5, wherein said at least one roughened region of said top surface of said first conductive semiconductor layer is a surrounding region that surrounds said first electrode and is roughened, a width of said surrounding region of said first conductive semiconductor layer ranging from 0.5 μm to 3 μm.

7. The light-emitting device as claimed in claim 1, wherein said first mesa side wall has a surface roughness that is smaller than that of said first mesa surface, each of said side walls of said active layer and said first conductive semiconductor layer having a surface roughness no greater than 0.2 μm.

8. The light-emitting device as claimed in claim 5, wherein a surface roughness of said at least one roughened region on said first conductive semiconductor layer ranges from 0.2 μm to 1 μm.

9. The light-emitting device as claimed in claim 1, wherein a distance from an edge of said first mesa surface to said first mesa side wall ranges from 0.5 μm to 10 μm.

10. The light-emitting device as claimed in claim 1 further comprising a second mesa surface defined by said second conductive semiconductor layer and located around said first mesa surface, said second mesa surface having a height that is smaller than that of said first mesa surface and that ranges from 0.2 μm to 3.5 μm.

11. The light-emitting device as claimed in claim 1 further comprising a reflection layer located below said second conductive semiconductor layer and a second mesa surface that is located at a peripheral portion of said reflection layer exposed from said second conductive semiconductor layer, a height of said second mesa surface being smaller than that of said first mesa surface.

12. The light-emitting device as claimed in claim 10, wherein said second mesa surface has a surface roughness that is smaller than that of said first mesa surface.

13. The light-emitting device as claimed in claim 12, wherein said surface roughness of said second mesa surface is no greater than 0.2 μm.

14. The light-emitting device as claimed in claim 10, further comprising a second mesa side wall that is defined by a side wall of said second conductive semiconductor layer and that intersects said second mesa surface, wherein a distance from an edge of said second mesa surface to said second mesa side wall ranges from 8 μm to 15 μm.

15. The light-emitting device of claim 1, wherein the light-emitting device emits one of red light and infrared light.

16. A method for manufacturing a light-emitting device, comprising the steps of:
S1) forming a semiconductor epitaxial structure that includes a first conductive semiconductor layer, a second conductive semiconductor layer, and an active layer disposed between the first conductive semiconductor layer and the second conductive semiconductor layer;
S2) roughening a surface of the first conductive semiconductor layer that is away from the active layer;
S3) removing a portion of the first conductive semiconductor layer and of the active layer to form a first mesa surface and to expose a side wall of the active layer and a side wall of the first conductive semiconductor layer, the first mesa surface being defined by a portion of the second conductive semiconductor layer, the side walls of the active layer and the first conductive semiconductor layer defining a first mesa side wall.

17. The method as claimed in claim 16, wherein in step S2), the first mesa side wall has a side wall bottom end connected to the first mesa surface to form a connection portion, which is constituted of the side wall bottom end and a mesa surface proximal region of the first mesa surface that adjoins the side wall bottom end, the mesa surface proximal region having a roughened structure.

18. The method as claimed in claim 16 further comprising the step of removing a portion of the second conductive semiconductor layer to form a second mesa surface and to expose a second mesa side wall, the second mesa surface being formed on the second conductive semiconductor layer, a height of the second mesa surface being smaller than that of the first mesa surface.

19. The method as claimed in claim 16 further comprising the steps of: forming a reflection layer on the second conductive semiconductor layer; and removing a portion of the second conductive semiconductor layer to expose a portion of the reflection layer and to thereby form a second mesa surface on a top surface of the reflection layer and expose a second mesa side wall of the second conductive semiconductor layer.

20. A light-emitting apparatus, comprising a packaging substrate and at least one light-emitting device as claimed in claim 1 disposed on said packaging substrate.
